(19) United States
(12) Patent Application Publication
(10) Pub. No.: US 2024/0409050 A1
(43) Pub. Date: Dec. 12, 2024

(54) Controller Assembly and a Chassis System for a Vehicle

(71) Applicants: Robert Bosch GmbH, Stuttgart (DE); Bosch Automotive Products (Suzhou) Co. Ltd., Suzhou (CN)

(72) Inventor: Jian Fan, Suzhou (CN)

(21) Appl. No.: 18/734,163

(22) Filed: Jun. 5, 2024

(30) Foreign Application Priority Data
Jun. 9, 2023 (CN) 2023 2146 4690.7

(51) Int. Cl. B60R 21/01; H01B 7/00; H05K 1/18; H05K 7/14

(52) U.S. Cl. CPC B60R 21/01; H01B 7/0045; H05K 1/181; H05K 7/14; B60R 2021/01286

(57) ABSTRACT

A controller assembly for a vehicle includes a fixed module suitable for mounting on vehicles and having a primary extension plane extending in the longitudinal direction and transverse direction. The fixed module has a first connection structure and a second connection structure on the primary extension plane. The controller assembly further includes at least one functional module, with a carrier, an electronic component arranged on the carrier, and a wire harness connected to the electronic components. The wiring harness extends from one side of the carrier. The functional module has a mating structure on the carrier configured to be mated to the first connecting structure or the second connecting structure in a detachable manner. When the mating structure is mated to the first connecting structure, the side of the carrier is parallel to the longitudinal direction, and when the mating structure is mated to the second connecting structure, the side of the carrier is parallel to the transverse direction. Advantages include being able to accommodate space requirements and avoiding interference of the harness with other components

This application claims priority under 35 U.S.C. § 119 to patent application no. CN 2023 2146 4690.7, filed on Jun. 9, 2023 in China, the disclosure of which is incorporated herein by reference in its entirety.

### BACKGROUND

The disclosure relates to the field of vehicles, and in particular, to a controller assembly for a vehicle. The present disclosure also relates to a corresponding chassis system for a vehicle. In recent years, with the advancement of technology and the improvement of living standards, people have become increasingly demanding for the functionality and intelligence of vehicles. To this end, multiple controllers are installed in vehicles to realize different functions. However, due to limitations in installation positions and space, the electrical wiring harness of the controllers can easily interfere with other components of the vehicle.

### SUMMARY

Therefore, the object of the present disclosure is to propose an improved controller assembly for vehicles. The installation orientation of the controller assembly can be flexibly adjusted to accommodate the spatial requirements of the installation position and to avoid interference of the wiring harness for the controller assembly with other components of the vehicle, so as to achieve smooth routing of the wiring harness.

According to a first aspect of the present disclosure, a controller assembly for a vehicle is provided, wherein the controller assembly comprises at least:
a fixed module configured for installation on the vehicle and having a primary extension plane extending in a longitudinal direction as well as a transverse direction perpendicular to the longitudinal direction, wherein the fixed module is provided with a first connecting structure and a second connecting structure on the primary extension plane; and
at least one functional module having a carrier, with an electronic component arranged on the carrier and a wiring harness electrically connected to the electronic component, of which the wiring harness extends from one side of the carrier, wherein the functional module is provided with a mating structure on the carrier, and the mating structure is configured to be mated to the first connecting structure or second connecting structure in a detachable manner, wherein when the mating structure is mated to the first connecting structure, the side of the carrier is parallel to the longitudinal direction, and when the mating structure is mated to the second connecting structure, the side of the carrier is parallel to the transverse direction.

Compared with the prior art, in the controller assembly of the present disclosure, the controller assembly comprises a fixed module and a functional module constructed separately. The fixed module has a first connecting structure and a second connecting structure on the primary extension plane, and the functional module has a mating structure on the carrier configured to be mated to the first connecting structure or the second connecting structure in a detachable manner, wherein when the mating structure is mated to the first connecting structure, the side of the functional module's carrier is parallel to the longitudinal direction of the fixed module's primary extension plane; conversely, when the mating structure is mated to the second connecting structure, the side of the carrier is parallel to the transverse direction of the primary extension plane. Thus, by adjusting the mating structure of the functional module and the connecting structures of the fixed module, the orientation of the wiring harness electrically connected to the electronic component can be flexibly changed, thereby avoiding interference with other components of the vehicle and facilitating the easier and simpler routing of the wiring harness.

Exemplarily, the first connecting structure comprises two first connecting portions disposed at the longitudinal ends of the primary extension plane; and/or, the second connecting structure comprises two second connecting portions disposed at the transverse ends of the primary extension plane; and/or, the mating structure comprises two mating portions disposed at the ends of the carrier, adjacent to its sides.

Exemplarily, the first connecting portions are centrally arranged in the transverse direction at the longitudinal end; and/or, the second connecting portion is centrally arranged in the longitudinal direction at the transverse end; and/or, the first connecting portion and the second connecting portion are configured structurally identical; and/or, the controller assembly is symmetrically configured in the longitudinal and/or transverse directions.

Exemplarily, the longitudinal extension dimension of the primary extension plane is greater than the transverse extension dimension, such that the primary extension plane is essentially configured as a rectangle.

Exemplarily, the functional module comprises a first functional module and a second functional module, wherein the distance between the first mating portions of the first mating structure of the first functional module is equal to the distance between the first connecting portions of the first connecting structure, such that the first mating structure of the first functional module is configured to be mated to the first connecting structure; the distance between the second mating portions of the second mating structure of the second functional module is equal to the distance between the second connecting portions of the second connecting structure, such that the mating structure of the second functional module is configured to be mated to the second connecting structure.

Exemplarily, the extension dimension of the side of the carrier of the first functional module is essentially equal to the longitudinal extension dimension of the primary extension plane; and/or, the extension dimension of the side of the carrier of the second functional module is essentially equal to the transverse extension dimension of the primary extension plane.

Exemplarily, the fixed module is configured for installation on the vehicle by way of a threaded connection and is provided with threaded holes on the primary extension plane; and/or the controller assembly is constructed as an airbag controller; and/or the controller assembly is configured for installation on the chassis of the vehicle.

Exemplarily, the corners of the primary extension plane are convexly configured with the threaded holes disposed in the depicted corners; and/or, the primary extension plane is disposed with at least two threaded holes arranged along the diagonal of the primary extension plane.

According to a second aspect of the present disclosure, a chassis system for a vehicle is provided, wherein the chassis system comprises at least a chassis and a controller assembly according to the present disclosure, with the controller assembly installed on the chassis.

Exemplarily, the chassis has a receiving recess in which the controller assembly is installed, wherein the receiving recess is bounded by recess edges parallel to each other, and the wiring harness of the functional module of the controller assembly runs through the receiving recess; and/or the controller assembly is arranged at a location on the chassis corresponding to the dashboard or center console of the vehicle.

### BRIEF DESCRIPTION OF THE DRAWINGS

The principles, features and advantages of the present disclosure can be better understood with a more detailed description of the present disclosure provided below with reference to the accompanying drawings. The accompanying drawings include the following:

FIG. 1 shows a partial schematic view of a chassis system for a vehicle according to an exemplary example of the present disclosure;

FIG. 2 shows a schematic view of the fixed module of the controller assembly according to an exemplary example of the present disclosure;

FIG. 3a and FIG. 3b respectively show schematic views of the first functional module and the second functional module of the controller assembly according to an exemplary example of the present disclosure.

### DETAILED DESCRIPTION

In order to make the technical issues to be addressed by the present utility, the technical solutions and beneficial technical effects are clearer and more understandable, the following will provide a more detailed explanation of the present disclosure in conjunction with accompanying drawings and multiple exemplary examples. It should be understood that the specific examples described here are intended only to explain the present disclosure and are not intended to limit the scope of protection of the present disclosure.

In the accompanying drawings, the size of each constituent element, the thickness of a layer, or an area is sometimes exaggerated for clarity. Thus, the shape and size of each component in the accompanying drawings do not reflect the true scale.

In the description of the present disclosure, unless otherwise expressly specified and defined, the terms “install”, “connected”, “connecting”, “fixed” and other terms shall be broadly understood. For example, they may refer to fixed connections or detachable connections; involve connections through material locking, form-locking, or force locking; refer to direct connections or connections through intermediaries; or refer to connections involving internal elements between two components or the interaction between two components, unless otherwise explicitly specified For those of ordinary skill in the art, the specific meaning of the above terms in the present disclosure may be understood based on the specific context.

It should be understood that in this document, terms such as “first”, “second”, etc., are used for descriptive purposes only and should not be construed as indicating or implying relative importance. Furthermore, such terms should not be understood as implying a specific quantity of the indicated technical features. Features defined as “first” and “second” may expressly or implicitly mean that at least one of the features is included.

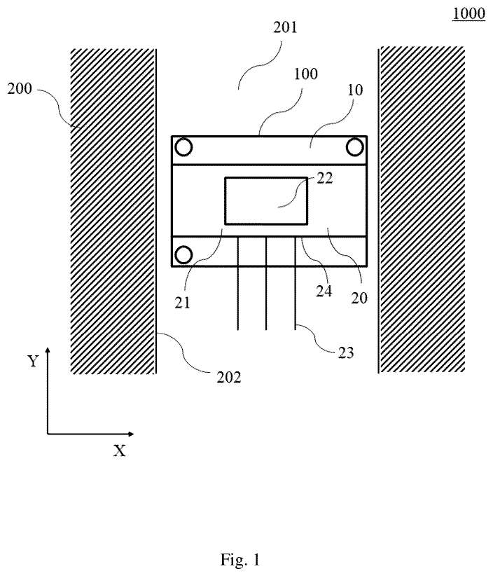

FIG. 1 shows a partial schematic view of a chassis system 1000 for a vehicle according to an exemplary example of the present disclosure.

As shown in FIG. 1, the chassis system 1000 comprises at least a controller assembly 100 and a chassis 200 according to the present disclosure, wherein the controller assembly is installed on the chassis and configured as an airbag controller. Here, the controller assembly 100 is specifically arranged at a location on the chassis 200 corresponding to the dashboard or center console of the vehicle, so as to better sense acceleration signals. It is of course also conceivable that the controller assembly 100 is configured as another controller that is considered meaningful by those skilled in the art and is arranged at other locations on the vehicle.

Exemplarily, as shown in FIG. 1, the chassis 200 has a receiving recess 201 that is bounded by recess edges 202 parallel to each other, and the controller assembly 100 is fixedly installed within the receiving recess 201.

As shown in FIG. 1, the controller assembly 100 comprises a fixed module 10, which can be fixedly installed in a detachable manner in the receiving recess 201 of the chassis 200 of the vehicle. In particular, the fixed module 10 is installed on the chassis 200 of the vehicle by way of a threaded connection. Here, fixed module 10 has a primary extension plane 11 extending along the longitudinal direction X and the transverse direction Y perpendicular to the longitudinal direction X, wherein the longitudinal direction corresponds, for example, to the front-rear direction of travel of the vehicle.

As shown in FIG. 1, the controller assembly 100 comprises a functional module 20 having a carrier 21, an electronic component 22 arranged on the carrier 21, and a wiring harness 23 electrically connected to the electronic component 22. The wiring harness 23 provides power and signal connections to the electronic component 22, which is centrally arranged on the carrier 21, wherein the wiring harness 23 extends from one side 24 of the carrier 21. Here, the functional module 20 of the controller assembly 100 is configured and assembled separately from the fixed module 10, such that the wiring harness 23 of the functional module 20 runs through the receiving recess 201.

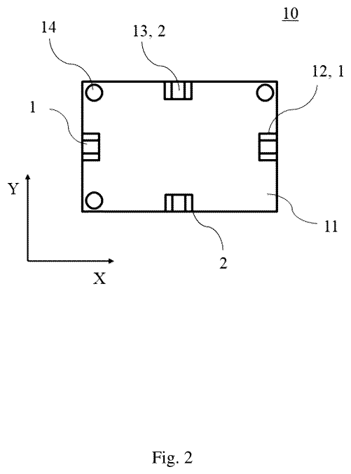

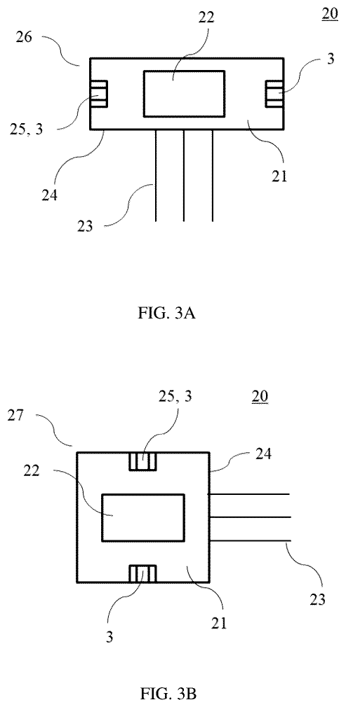

To this end, the fixed module 10 is provided with a first connecting structure 12 and a second connecting structure 13 on the primary extension plane 11, while the functional module 20 is provided with a mating structure 25 on the carrier 21, wherein the mating structure is configured to be mated to the first connecting structure 12 or the second connecting structure 13 in a detachable manner, so as to achieve the assembly of the functional module 20 and the fixed module 10; wherein, when the mating structure 25 is mated to the first connecting structure 12, the side 24 of the carrier 21 is parallel to the longitudinal direction X and the wiring harness 23 extends from this side; whereas when the mating structure 25 is mated to the second connecting structure 13, the side 24 of the carrier 21 is parallel to the transverse direction Y. This allows for adjustments to the installation orientation of the functional module 20 based on the installation position and installation space of the controller assembly 100, such as the specific conditions of the receiving recess 201, so as to change the routing of the wiring harness 23 and avoid interference between the wiring harness 23 and other components of the vehicle, such as the recess edges 202. See FIG. 2, FIG. 3a, and FIG. 3b for details. In the framework of the present disclosure, a “mating connection” should be understood as a connection involving form-locking and/or force-locking.

FIG. 2 shows a schematic view of the fixed module 10 of the controller assembly 100 according to an exemplary example of the present disclosure. FIG. 3a and FIG. 3b respectively show schematic views of the first functional module 26 and the second functional module 27 of the controller assembly 20 according to an exemplary example of the present disclosure.

As shown in FIG. 2, the fixed module 10 has a primary extension plane 11 extending along the longitudinal direction X and the transverse direction Y perpendicular to the longitudinal direction X, wherein the longitudinal extension dimension of the primary extension plane 11 is larger than the transverse extension dimension, such that the primary extension plane 11 is essentially configured as a rectangle. However, it is also conceivable that the longitudinal extension dimension of the primary extension plane 11 is equal to the transverse extension dimension, such that the main extension plane 11 is configured as a square.

As shown in FIG. 2, the first connecting structure 12 of the fixed module 10 comprises two first connecting portions 1 disposed at the longitudinal ends of the primary extension plane 11, wherein the longitudinal ends are the opposing ends along the longitudinal direction X of the primary extension plane 11, and the second connecting structure 13 of the fixed module 10 comprises two second connecting portions 2 positioned at the transverse ends of the primary extension plane 11, wherein the transverse ends are the opposing ends along the transverse direction Y of the primary extension plane 11. In addition, as shown in FIG. 3a and FIG. 3b, the mating structure 25 of the functional module 20 comprises two mating portions 3 disposed at the ends of the carrier 21, adjacent to the side 24. This enables the edge regions of the fixed module 10 and the functional module 20 to be fully utilized and avoids any impact on the arrangement of the electronic component 22 of the functional module 20. Here, when the mating structure 25 is mated to the first connecting structure 12, the mating portions 3 of the mating structure 25 are individually connected to the first connecting portions 1 of the first connecting structure 12 in a form-locking or force-locking manner, such that the side 24 of the functional module 20 is parallel to the longitudinal direction X and the wiring harness 23 runs through the lateral direction Y in the receiving recess 201, as shown in FIG. 1. When the mating structure 25 is mated to the second connecting structure 13, the mating portions 3 of the mating structure 25 are individually connected to the second connecting portions 2 of the second structure 13 in a form-locking or force-locking manner, such that the side 24 of the functional module 20 is parallel to the transverse direction Y and the wiring harness 23 runs through the longitudinal direction X. This applies to situations where the receiving recess 201 extends along the longitudinal direction X. Of course, it is also conceivable that the first connecting structure 12, the second connecting structure 13 and the mating structure 25 are configured in other forms and have other numbers of connecting portions and mating portions that are considered meaningful by those skilled in the art.

Exemplarily, as shown in FIG. 2, the first connecting portions 1 are centrally arranged at the longitudinal ends of the primary extension plane 11 in the transverse direction Y, while the second connecting portions 2 are centrally arranged at the transverse ends of the primary extension plane X in the longitudinal direction X. This can achieve a reliable connection between the fixed module 10 and the functional module 20 in the longitudinal direction X or the transverse direction Y, while avoiding uneven stress distribution. In particular, the first connecting portion 12 and the second connecting portion 13 are configured structurally identical and the controlled assembly 100 is symmetrically configured in the longitudinal direction X and/or the transverse direction Y, which enables cost-effective manufacturing and simplified assembly of the controlled assembly 100.

Exemplarily, as shown in FIG. 3a and FIG. 3b, the functional module 20 comprises a first functional module 26 and a second functional module 27, wherein the distance between the first mating portions 3 of the mating structure 25 of the first functional module 26 is equal to the distance between the first connecting portions 1 of the first connecting bridge 12, allowing the mating structure 25 of the first functional module 26 to be mated to the first connecting structure 12 of the fixed module 10; and the distance between the mating portions 3 of the mating structure 25 of the second functional module 27 is equal to the distance between the second connecting portions 2 of the second connecting structure 13, allowing the mating structure 25 of the second functional module 27 to be mated to the second connecting structure 13 of the fixed module 10. Here, the electronic component 22 of the first functional module 26 and the second functional module 27 are the same. In this case, based on the desired routing of the wiring harness 23, a choice may be made between the first functional module 26 and the second functional module 27, with the selected functional module then mated to the corresponding connecting structure to achieve the desired routing of the harness 23. This helps avoid interference between the wiring harness 23 and other components of the vehicle. Furthermore, it is also possible for the controller assembly 100 to comprise only one functional module 20 when the primary extension plane 11 of the fixed module 10 is configured as a square, wherein the distance between the first connecting portions 1 of the first connecting structure 12 of the fixed module 10 is equal to the distance between the second connecting portions 2 of the second connecting structure 13, and the distance is equal to the distance between the mating portions 3 of the mating structure 25 of the functional module 20. In this case, the functional module 20 may be directly rotated to adjust the mating connection between the mating structure 25 and the first connecting structure 12 or the second connecting structure 13, without the need to set up additional functional modules.

Exemplarily, the extension dimension of the side 24 of the carrier 21 of the first functional module 26 is essentially equal to the longitudinal extension dimension of the primary extension plane 11, such that when the first functional module 26 is assembled on the fixed module 10, the ends of the first functional module 26, adjacent to the side 24, are disposed flush with the longitudinal ends of the primary extension plane 11. In addition, the extension dimension of the side 24 of the carrier 21 of the second functional module 27 is essentially equal to the longitudinal extension dimension of the primary extension plane 11, such that when the second functional module 27 is assembled on the fixed module 10, the ends of the second functional module 27, adjacent to the side 24, are disposed flush with the transverse ends of the primary extension plane 11. This enables the controller assembly 100 to be compactly constructed and simplifies the installation of the controller assembly 100.

Exemplarily, as shown in FIG. 2, the fixed module 10 is configured for installation on the chassis 200 of a vehicle by way of a threaded connection and has threaded holes 14 provided on the primary extension plane 11. Here, the primary extension plane 11 is provided with at least two threaded holes 14, arranged along the diagonal line of the primary extension plane 11, which enables the secure installation of the fixed module 10 on the chassis 200. Of course, it is also conceivable that the primary extension plane 11 is provided with more, for example, three threaded holes 14.

Exemplarily, the corners where the sides of the primary extension plane 11 meet are configured to be convex, and the threaded holes 14 are provided in the corners, thus effectively increasing the distance between the screws used for the installation of the fixed module 10 and the functional module 20 assembled on the fixed module 10, and thereby preventing the screws from obstructing the assembly of the functional module 20 on the fixed module 10.

The preceding explanation of the embodiments only describes the present disclosure within the framework of the examples provided. Of course, as long as it is technically feasible, the various features of the embodiments may be freely combined with each other without departing from the framework of the present disclosure.

Other advantages and alternative embodiments of the present disclosure will be apparent to those skilled in the art. Accordingly, in its broader sense, the present disclosure is not limited to the specific details, representative structures, and exemplary examples shown and described. Instead, those skilled in the art may make various modifications and substitutions without departing from the fundamental spirit and scope of the present disclosure.

What is claimed is:

1. A controller assembly for a vehicle, comprising:
a fixed module configured to be installed on the vehicle and having a primary extension plane extending in a longitudinal direction and a transverse direction perpendicular to the longitudinal direction, wherein the fixed module is provided with a first connecting structure and a second connecting structure on the primary extension plane; and
at least one functional module having a carrier, with an electronic component arranged on the carrier and a wiring harness electrically connected to the electronic component, of which the wiring harness extends from one side of the carrier, wherein the functional module is provided with a mating structure on the carrier, and the mating structure is configured to be mated to the first connecting structure or the second connecting structure in a detachable manner,
wherein when the mating structure is mated to the first connecting structure, the side of the functional module's carrier is parallel to the longitudinal direction, and
wherein when the mating structure is mated to the second connecting structure, the side of the carrier is parallel to the transverse direction.

2. The control assembly according to claim 1, wherein:
the first connecting structure comprises two first connecting portions disposed at the longitudinal ends of the primary extension plane; and/or
the second connecting structure comprises two second connecting portions disposed at the longitudinal ends of the primary extension plane; and/or
the mating structure comprises two mating portions disposed at the ends of the carrier, adjacent to the side.

3. The control assembly according to claim 2, wherein:
the first connecting portion is centrally arranged at the longitudinal end in the transverse direction, and/or
the second connecting portion is centrally arranged at the transverse end in the longitudinal direction, and/or
the first connecting portion and the second connecting portion are configured structurally identical, and/or
the controller assembly is configured symmetrically in the longitudinal direction and/or in the transverse direction.

4. The control assembly according to claim 2, wherein:
the longitudinal extension dimension of the primary extension plane is greater than the transverse extension dimension, such that the primary extension plane is essentially configured as a rectangle.

5. The control assembly according to claim 4, wherein:
the functional module comprises a first functional module and a second functional module,
the distance between the first mating portions of the mating structure of the first functional module is equal to the distance between the first connecting portions of the first connecting structure, such that the mating structure of the first functional module is configured to be mated to the first connecting structure, and
the distance between the mating portions of the mating structure of the second functional module is equal to the distance between the second connecting portions of the second connecting structure, such that the mating structure of the second functional module is configured to be mated to the second connecting structure.

6. The control assembly according to claim 5, wherein:
the extension dimension of the side of the carrier of the first functional module is essentially equal to the longitudinal extension dimension of the primary extension plane, and/or
the extension dimension of the side of the carrier of the second functional module is essentially equal to the transverse extension dimension of the primary extension plane.

7. The control assembly according to claim 1, wherein:
the fixed module is configured for installation on the vehicle by way of a threaded connection and is provided with threaded holes on the primary extension plane; and/or
the controller assembly is constructed as an airbag controller; and/or
the controller assembly is configured for installation on the chassis of the vehicle.

8. The control assembly according to claim 7, wherein:
the corners of the primary extension plane are configured to be convex, and the threaded holes are provided in the corners; and/or
the primary extension plane is disposed with at least two threaded holes arranged along the diagonal of the primary extension plane.

9. A chassis system for a vehicle, comprising:
at least a chassis; and
a controller assembly according to claim 1,
wherein the controller assembly is installed on the chassis.

10. The chassis system according to claim 9, wherein:
the chassis has a receiving recess in which the controller assembly is installed,
the receiving recess is bounded by recess edges parallel to each other, and the wiring harness of the functional module of the controller assembly runs through the receiving recess;
and/or the controller assembly is arranged at a location on the chassis corresponding to a dashboard or a center console of the vehicle.
